(19) United States
(12) Patent Application Publication
(10) Pub. No.: US 2026/0359521 A1
(43) Pub. Date: Nov. 12, 2026

(54) METHOD FOR CREATING OR UPDATING A DIGITAL TWIN FOR AN AUTOMATION FIELD DEVICE

(71) Applicant: Endress+Hauser Process Solutions AG, Reinach (CH)

(72) Inventors: Markus Wohlgemuth, Erschwil (CH); Francois Ichtertz, Dornach (CH); Alexander Franke, Birsfelden (CH); Jawad Tayyub, Maulburg (DE)

(21) Appl. No.: 19/137,982

(22) PCT Filed: Nov. 30, 2023
(86) PCT No.: PCT/EP2023/083755

§ 371 Date: Jun. 11, 2025

(30) Foreign Application Priority Data
Dec. 20, 2022 (DE) 10 2022 134 113.5

(51) Int. Cl. G06F 30/27

(52) U.S. Cl. CPC G06F 30/27

(57) ABSTRACT

A method for creating or updating a digital twin for an automation field device includes: optically capturing a recording of the field device using an operating unit; transmitting the recording to a cloud-based platform; determining a type of the field device and/or a description of a possible application of the field device based on the recording, wherein a pre-trained AI or machine learning algorithm analyzes the recording using existing recordings of known types of field devices and/or design data; and creating a digital twin of the field device or augmenting an existing digital twin, wherein the type of the field device and/or the description of the possible application are added to the digital twin.

The invention relates to a method for creating or updating a digital twin for an automation field device.

Field devices that are used in industrial installations are already known from the prior art. Field devices are often used in process automation technology, as well as in manufacturing automation technology. In principle, all devices that are used near the process and supply or process process-relevant information are referred to as field devices. Field devices are thus used for detecting and/or influencing process variables. Measuring devices, or sensors, are used for detecting process variables. They are used, for example, for pressure and temperature measurement, conductivity measurement, flow measurement, pH measurement, fill-level measurement, etc., and detect the corresponding process variables of pressure, temperature, conductivity, pH value, fill level, flow, etc. Actuators are used for influencing process variables. These actuators are, for example, pumps and valves that can influence the flow of a fluid in a pipe or the fill level in a tank. In addition to the aforementioned measuring devices and actuators, field devices are also understood to include remote I/O's, radio adapters, or, generally, devices that are arranged at the field level.

A multitude of such field devices are produced and marketed by the Endress+Hauser group.

In modern industrial plants, field devices are usually connected to superordinate units via communications networks such as fieldbuses (Profibus®, Foundation® Fieldbus, HART®, etc.). Usually, the superordinate units are control systems (DCS) or control units, such as an SPC (stored program control). The superordinate units are used for, among other things, process control, process visualization, and process monitoring, as well as commissioning of the field devices. The measured values recorded by the field devices, especially by sensors, are transmitted via the respective bus system to a (or in some cases a plurality of) superordinate unit(s). In addition, data transmission from the superordinate unit via the bus system to the field devices is also required, especially for configuration and parameterization of field devices and for controlling actuators.

In the course of Industry 4.0 or IIoT (“Industrial Internet of Things”), the data generated by the field devices are also frequently collected directly from the field by means of what are known as data conversion units, which are referred to as “edge devices” or “cloud gateways,” for example, and are transmitted automatically to a central, cloud-based platform. The terms cloud-based platform, cloud, and server are to be understood as synonymous in the context of this application.

The cloud-based platform contains one or more such cloud applications. A cloud application is a program which runs on such a cloud-based platform or is integrated into it. A user can connect to the cloud-based platform via the Internet and perform modifications in the corresponding cloud applications of the cloud-based platform and/or operate them, i.e., write data to the cloud applications, read data from the cloud applications, and/or edit said data.

A digital twin, also called a digital image, is a virtual representation of the field device which comprises the same configuration, parameter values, current device status, algorithms, etc., as the field device. The digital twin therefore has all the properties of the field device which describe the field device in full for its intended purpose. It is provided that the field device and the digital twin always be identical. A change in properties of the field device leads to synchronization (via Industry 4,0, or IIoT technologies) with the digital twin, such that the properties of the digital twin are updated accordingly. The digital twin is, for example, integrated into a cloud application.

A digital twin is usually created after a field device is ordered or during its production. However, it often happens that properties of the field device change between the creation of the digital twin and the commissioning of the field device, as a result of which the digital twin does not completely match the properties of the field device after the commissioning of the field device.

There are what are known as “scanner apps” which run on mobile devices and allow the mobile devices to detect the field devices located in the field. It is possible to take photos of a field device and enter meta information such as a description of the application and/or the type of field device. The app can access the digital twin and supplement it with the photo and metadata.

This information must be entered separately and manually for each individual field device, even for identical or similar objects in comparable applications. To get a complete impression of the installation and its surroundings, multiple photos must be taken.

A digital twin can also be created manually at a later date and, for example, augmented by means of the information recorded by the scanner app. In addition to the disadvantage that this requires a great deal of manual effort, there is also no fault check or plausibility check.

Based upon this problem, the invention is based upon the object of presenting a method which allows an incomplete digital twin of a field device to be completed in a simple manner or a complete digital twin for a field device to be created.

The object is achieved by a method for creating or updating a digital twin for an automation field device, comprising:
optically capturing a recording of the field device using an operating unit;
transmitting the recording to a cloud-based platform;
determining a type of the field device and/or a description of a possible application of the field device on the basis of the recording, wherein, for the determining step, a pre-trained AI or machine learning algorithm analyzes the recording using existing images of known types of field devices and/or design data; and
creating a digital twin of the field device, wherein the type of the field device and/or the description of the possible application are added to the digital twin when it is created, or augmenting an existing digital twin of the field device to include the type of the field device and/or the description of the possible application of the field device.

The method according to the invention makes it possible to automatically load data relating to field devices into a digital twin of the field device. In case no digital twin exists for the field device, a new digital twin can be created on the cloud-based platform. For both variants, the user needs only to optically capture a recording of the field device using the operating unit. The cloud-based platform then uses the AI or machine learning algorithm to independently determine the device type of the field device and/or the description of a possible application of the field device. For this purpose, the AI or machine learning algorithm is pre-trained with training data, which includes images of field devices and/or design data as input data and defined device types or descriptions of applications as output data. An application description contains information about the task of the field device (e.g., measuring the temperature in a container, etc.), information about special configurations of the field device (e.g., a hygienic housing for applications in the food industry, etc.), and application-specific warnings and environmental information.

The digital twin is augmented to include the device types and descriptions obtained in this way. To do this, the user selects the relevant digital twin or has it determined using the cloud-based platform. In case no digital twin exists for this field device, the cloud-based platform creates a corresponding digital twin. For this purpose, the user must provide identification information for the field device (or a tag or serial number).

Field devices that are cited in connection with the method according to the invention are already listed as examples in the introductory part of the description.

According to an advantageous embodiment of the method, it is provided that, in the event that no unique type of the field device and/or no unique description of a possible application of the field device can be determined, a plurality of possible types of the field device or a plurality of possible descriptions be suggested to a user. The AI or machine learning algorithm can for this purpose assign a degree of possible agreement to the possible types of field devices or to the plurality of possible descriptions. The possible types of the field device or the plurality of possible descriptions are presented to the user on the operating unit, wherein the user then selects the device type or the description via the operating unit.

One embodiment of the method provides that, to create the description of a possible application, at least one further piece of information be determined or made available, which is then analyzed by the AI or machine learning algorithm. This can, for example, be a recording of the environment of the field device, location information regarding the field device, and/or information regarding the orientation of the operating unit when the recording is captured. When using this further piece of information, the AI or machine learning algorithm must be trained with further training data containing the further piece of information mentioned.

According to an advantageous embodiment of the method, it is provided that, in the event that no unique type of the field device and/or no unique description of a possible application of the field device can be determined, even if the at least one further piece of information is used, additional information regarding the field device and/or about the application be requested from the user, wherein in particular a catalog of questions is used. In this case, the queries are carried out by the operating unit or cloud-based query, wherein the queries are presented to the user by means of the operating unit and wherein the user enters the additional information via the operating unit. The further piece of information is requested in particular in a context-related manner. For example, the user be asked which process medium flows through a pipeline, to independently determine the correct value of the density parameter of the field device for a flow measurement. If the user does not know the measuring medium, the user can also formulate its properties (“colorless,” “odorless,” etc.), allowing the cloud-based platform to independently deduce the requested missing piece of information from these properties.

According to one embodiment of the method, it can further be provided that the recording comprise one or more two-dimensional images of the field device and/or a video of the field device. The images preferably show different angles or views of the field device. This allows, for example, field device types which have a similar upper side, but differ significantly when viewed from other angles, to be precisely distinguished from one another. The video should ideally include a pan or change of perspective around the field device.

In a further embodiment, the design data are, advantageously, CAD data. These do not have to be “real” data, but, rather, data which were created during the design of the measuring point in which the field device is installed or during the creation of the field device itself. This allows the AI or machine learning algorithm to take into account details which are not contained in the training data photos, making subsequent recognition more precise.

In a further embodiment of the method, after the type of the field device or the description is determined, a three-dimensional model of the field device is displayed on the operating unit, which three-dimensional model shows the same viewing angle of the field device as the recording. This allows the user to correctly identify the device; the user can confirm that the field device is the correct field device by comparing the one in front of them with the displayed three-dimensional model. The three-dimensional model is also loaded into the digital twin or linked thereto so that the user can access it via the cloud-based platform. In addition to the field device, the three-dimensional model can also comprise other components (e.g., containers, pipelines, network devices, network cabling, other field devices, etc.) of the measuring point which are located in close proximity to the field device and/or are connected thereto.

In this case, it can be provided that the three-dimensional model be created using at least two images of field devices of the same type. Alternatively, the three-dimensional model can also be created from the design data.

According to an advantageous embodiment of the method, it is provided that the user confirm or reject the type of the field device and/or the description for the possible application, wherein the confirmation or rejection is fed to the AI or machine learning algorithm. By such feedback, the AI or machine learning algorithm is further trained. Through regular feedback, the AI or machine learning algorithm becomes more precise and delivers more accurate results. For example, this also results in behavior being trained at different times of day, when the brightness and color saturation of the recordings are different.

It can be provided that the AI or machine learning algorithm be used “globally,” i.e., that a plurality of users across systems access the AI or machine learning algorithm, provide feedback, and thus further train it.

A further embodiment provides that a mobile device, in particular a smartphone or a tablet, be used as the operating unit. An operating unit such as the “Field Xperts” marketed by the applicant or a wearable such as data glasses (e.g., Google Glasses) or a smartwatch can also be used with the method according to the invention if it has a camera.

The invention is explained in greater detail with reference to the following figure. Shown is:

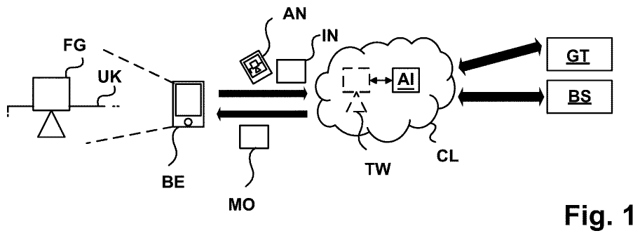

FIG. 1: an exemplary embodiment of the method according to the invention.

FIG. 1 shows a field device FG installed in a measuring point of a process engineering installation. In the present case, the field device FG is a fill-level measuring device which is designed to measure the fill level in a container.

The field device FG is in direct or indirect contact with one or more environmental components UK. In the present case, the environmental component UK shown is the tank to which the field device FG is attached.

For the field device FG, what is known as a digital twin TW is to be created on a cloud-based platform CL. A digital twin TW is a digital image of the field device FG and is to have the same properties, in particular the same configuration and the same parametering, as the field device FG itself.

For this purpose, an operating unit BE, in this case a mobile device in the form of a smartphone, is connected to the cloud-based platform CL via the Internet. For this purpose, the operating unit BE must authenticate itself to the cloud-based CL platform for example, using login data (such as username and password) and/or biometric authentication features (e.g., a fingerprint).

After successfully connecting to the cloud-based platform CL, the user chooses to create a new digital twin TW for a field device FG, which is still unknown. After entering identification information of the field device FG, e.g., a tag or a serial number, the operating unit BE uses its camera to capture a recording AN of the field device FG. The recording consists of at least one, but preferably two or more, photos of the field device FG, which photos should be taken from different angles. Alternatively, a video can be taken as the recording AN, which video should include a pan around the field device FG.

The recording AN is then transmitted to the cloud-based platform CL. An AI or machine learning algorithm AI implemented on the cloud-based platform CL then processes the recording AN. The processing is carried out in such a way that the AI or machine learning algorithm AI compares the recording to existing images of known types of field devices FG and/or design data. This can be done by training the AI or machine learning algorithm AI in advance with training data containing these known types and design data (e.g., CAD data). In particular, the AI or machine learning algorithm AI recognizes distinctive geometries or geometric curves of the field device FG and/or externally recognizable components, such as a display unit, an electrical connection, a flange, etc. As a result of the processing, a type GT of a field device FG and/or a description BS regarding a possible application of the field device FG is suggested to the user. In addition, a three-dimensional model MO of the field device FG is visualized on the operating unit BE. Such a three-dimensional model MO can be created from photos of field devices of the same type and/or using design data.

After user confirmation, the type GT of the field device FG, or the description BS and the three-dimensional model MO, are added to the digital twin TW.

In the event that the captured recording AN of the field device FG is not sufficient to accurately suggest the type GT or the description BS, further information IN is required for example, a recording of the surroundings of the field device FG, location information of the field device FG, and/or information regarding the orientation of the operating unit BE when the recording AN was captured. The further piece of information IN is fed to the AI or machine learning algorithm AI, which again suggests the type GT of the field device FG and/or a description BS of a possible application.

In case this further information IN is also not sufficient to reliably determine and suggest the type GT of the field device FG and/or a description BS of a possible application, additional information regarding the field device FG and/or the application will be requested from the user. For this purpose, a catalog of questions contained on the cloud-based CL platform is used. The queries are carried out by the operating unit BE or the cloud-based platform CL, wherein the queries are presented to the user by means of the operating unit BE and wherein the user enters the additional information via the operating unit.

After each step in which a suggestion is presented to the user, the user is to accept or reject this suggestion. This feedback is fed to the AI or machine learning algorithm so that it can be further trained and make even more precise suggestions.

If a digital twin TW already exists for the field device FG, the user selects it after authentication. After confirmation of the proposals, the digital twin TW is extended to include the type GT of the field device FG, the description BS, and/or the three-dimensional model MO.

### LIST OF REFERENCE SIGNS

AN recording
BE operating unit
BS description of a possible application of the field device
CL cloud-based platform
FG field device
GT types of field devices
IN further information
AI AI or machine learning algorithm
MO three-dimensional model of the field device
TW digital twin
UK environmental component

1-12. (canceled)

13. A method for creating or updating a digital twin of an automation field device, the method comprising:
optically capturing a recording of the field device using an operating unit;
transmitting the recording to a cloud-based platform;
determining a type of the field device and/or a description of a possible application of the field device based on the recording, wherein, for the determining, a pre-trained artificial intelligence (AI) or machine learning algorithm is configured to analyze the recording using existing images of known types of field devices and/or design data; and
creating a digital twin of the field device, wherein the type of the field device and/or the description of the possible application are including in the created digital twin; or
augmenting an existing digital twin of the field device to include the type of the field device and/or the description of the possible application of the field device.

14. The method according to claim 13, wherein, when no unique type of the field device and/or no unique description of a possible application of the field device is determined, a plurality of possible types of the field device or a plurality of possible descriptions are suggested to a user.

15. The method according to claim 14, wherein the user confirms or rejects the type of the field device and/or the description for the possible application, wherein the confirmation or rejection is provided to the AI or machine learning algorithm, and wherein the AI or machine learning algorithm is further trained with the confirmation or rejection.

16. The method according to claim 13, wherein, to create the description of a possible application, at least one further piece of information is determined or made available, which is analyzed by the AI or machine learning algorithm.

17. The method according to claim 16, wherein the at least one further piece of information includes a recording of a surroundings of the field device, location information of the field device, and/or information regarding an orientation of the operating unit when the recording is captured.

18. The method according to claim 16, wherein, when no unique type of the field device and/or no unique description of a possible application of the field device is determined using the at least one further piece of information, additional information regarding the field device and/or about the application is queried from the user, wherein a catalog of questions is used in the queries.

19. The method according to claim 18, wherein the queries are performed by the operating unit or the cloud-based platform, wherein the queries are presented to the user via the operating unit, and wherein the user enters the additional information via the operating unit.

20. The method according to claim 13, wherein the recording includes one or more two-dimensional images of the field device and/or a video of the field device.

21. The method according to claim 13, wherein the design data are computer-aided design data.

22. The method according to claim 13, wherein, after the type of the field device or the description is determined, a three-dimensional model of the field device is displayed on the operating unit, which three-dimensional model shows the same viewing angle of the field device as the recording.

23. The method according to claim 22, wherein the three-dimensional model is created based on at least two images of field devices of the same type.

24. The method according to claim 13, wherein the operating unit is a mobile device, a smartphone, or a tablet.
